(19) United States
(12) Patent Application Publication
(10) Pub. No.: US 2024/0302466 A1
(43) Pub. Date: Sep. 12, 2024

(54) MRI System Or MRSI System With A Coil Having A Unified Coil Assembly

(71) Applicant: Zepp Europe Holding B.V., Amsterdam-Duivendrecht (NL)

(72) Inventors: Jinghua Wang, Cupertino, CA (US); Kongqiao Wang, Hefei (CN); Tongtong Han, Hefei (CN); Li Guo, Hefei (CN)

(21) Appl. No.: 18/180,423

(22) Filed: Mar. 8, 2023

(51) Int. Cl. G01R 33/385

(52) U.S. Cl. CPC G01R 33/385

(57) ABSTRACT

A magnet resonance system including a magnet, gradient coils, and radiofrequency coils. The gradient coils have one or more first electrically conductive loops that provide spatial encoding as to a subject of the system. The radiofrequency coils have one or more second electrically conductive loops that transmit a radiofrequency field to excite nuclear spins and/or receive an MRI signal. All or a portion of the one or more first electrically conductive loops and the one or more second electrically conductive loops are shared. The present teachings provide a device that integrates part of one or more gradient coils into part of one or more RF coils in a magnetic resonance system.

### TECHNICAL FIELD

The present teachings provide a magnetic resonance system. The present teachings may integrate part of one or more gradient coils into part of one or more radiofrequency (RF) coils in a magnetic resonance system. The present teachings provide a prototype for integration of the RF coils and the gradient coils in a magnetic resonance system.

### BACKGROUND

Magnetic resonance imaging (MRI) is a widely used medical imaging modality. MRI techniques offer numerous advantages over other imaging techniques. Imaging with an MRI has far less risk of side effects than most other imaging modalities such as radioscopy with x-rays or computed tomography (CT) or positron emission tomography (PET) because patient and medical personal are not subjected to ionizing radiation exposure in the procedure. Every year, more than 35 million MRI scans are performed in the United States and more than 70 million MRI scans are performed worldwide. Doctors often recommend MRI for the diagnoses, treatment planning, and therapy assessment of various diseases, such as tumors, strokes, heart problems, prostate cancer, spine diseases, etc. A high-quality scan is important for maximizing the cost-effectiveness of MRI scans and making the right healthcare. Generally, a high-quality image requires high signal to noise ratio (SNR), high contrast between normal and pathological tissues, low levels of artifact, and reasonable and acceptable spatial-temporal resolution.

In order to obtain a detectable nuclear magnetic resonance (NMR) or magnetic resonance imaging (MRI) or magnetic resonance (MR) signal, the object being imaged (also referred to herein as “object” or “subject”) must be exposed to a static main magnetic field (usually designated as the B₀ field) which is as homogeneous as possible. The main magnetic field can be generated by a magnet of the MRI system. While the magnetic resonance images are being recorded, the main magnetic field has fast-switched gradient fields superimposed on it for spatial encoding, which are generated by gradient coils.

Typically, gradient coils are designed to produce a magnetic field component which is parallel to a direction of a main magnetic field. The magnetic fields generated by the gradient coils vary linearly in amplitude with position along one of the x, y, or z axes and are used to encode spatial information into the MR signal by creating a characterized resonance frequency at each location in the object being imaged by MRI system.

Moreover, using radio-frequency (RF) antennas, radio-frequency pulses are radiated into the objected being imaged. RF field of these RF pulses is normally designated as B₁⁺. Using these RF pulses, the nuclear spins of the atoms in the object being imaged are excited such that the atoms are deflected by a so-called “excitation flip angle” from their equilibrium position parallel to the main magnetic field B₀. The nuclear spins then precess or spin around the direction of the main magnetic field B₀. The processed nuclear spins can introduce the magnetic resonance signals that are recorded by RF receiver coil. The receiver coil can be either the same coil which was used to generate the RF pulses (e.g., a transceiver coil) or a separate receive-only coil.

In conventional MRI systems and/or MRSI systems, (a magnetic resonance system) gradient coils and radiofrequency coils (i.e. a transmit radiofrequency coil and/or a receiver radiofrequency coil) are independent in geometry, configuration, and driven circuits. The interaction between the gradient coils and the radiofrequency coils are minimized or eliminated by a conductive shielding being applied between the gradient coils and the radiofrequency coils.

Over past decades, several attempts have been made to integrate the components of MRI system to decrease the cost and complexity. Examples of which may be found in U.S. Pat. Nos. 9,880,242; 10,649,048; and 11,2095,10; Patent Application Publication Nos. 2015/0323628; and 2018/0210049 the teachings of which are all incorporated by reference herein in their entirety. Most of references focused on the integration between radiofrequency coils and B₀ shimming coils. Few references considered the integration between radiofrequency coils and gradient coils.

What is needed is a magnetic resonance that has a part of one or more RF coils integrated with part of one or more gradient coils such that a same amount of scanning may be performed or more scanning may be performed with fewer components, in a more compact space, or both.

### Definitions

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not.

Coil performance of transmit coil includes, but not limited to, uniformity of radio-frequency field, transmit efficiency and power deposition (e.g., specific absorption rate).

Image quality includes, but is not limited to, signal-to-noise ratio and its variations, contrast-to-noise and its variations, artifacts, spatial-temporal resolution, and accuracy. Accuracy is a metric indicating the difference between an acquired image and an image as a ground truth, or a difference between a result and a “true” value.

B₁⁺ is the positive circularly polarized component of a transversal transmit field of a RF field which is generated by a transmit coil. The transmit coil can be at least one of volume coil, surface coil, one conductive element of an array coils, or a combination thereof. The transversal transmit RF field can be decomposed into two rotating fields: the positive circularly polarized component B₁+, which rotates in the direction of nuclear magnetic moment precession (counterclockwise direction), and the negative circularly polarized component B₁⁻, which rotates opposite to the direction of precession (clockwise direction). In a magnetic resonance system, only the positive circularly polarized component of the transmitting field BIT contributes to the excitation of proton nuclei spins, while the negative circularly polarized component of the transmitting field B₁⁻ contributes to the receive sensitivity of a receiver coil.

Either inhomogeneous transmit or inhomogeneous receiver sensitivity or both can give rise to signal and contrast inhomogeneities in the acquired or reconstructed images. Without removing or sufficiently reducing these B₁ inhomogeneities (e.g., B₁⁺ and B₁⁻ inhomogeneities), the value of MRI images in clinic and research may be compromised.

### SUMMARY

The present teachings relate to a magnet resonance imaging system (MRI/MRSI) comprising: a magnet; gradient coils comprising one or more first electrically conductive loops that provide spatial encoding as to a subject of the system; and radiofrequency coils comprising one or more second electrically conductive loops that transmit a radiofrequency field to excite nuclear spins and/or receive a MRI signal; wherein all or a portion of the one or more first electrically conductive loops and the one or more second electrically conductive loops are shared.

The present teachings relate to a magnetic a magnetic resonance imaging (MRI) apparatus comprising: a plurality of electrically conductive loops; at least one or more first part of the plurality of the electrically conductive loops provides spatial encoding in the MRI apparatus; and at least of one or more second part of the plurality of the electrically conductive loops provides radiofrequency transmission that excite nuclear spins and/or reception of MRI radiofrequency signals in the MRI apparatus; wherein all or a portion of the one or more first part of the plurality of electrically conductive loops and the one or more second part of the electrically conductive loops are shared.

The present teachings provide, the conductive elements are comprised of one or more of ground dipole coil, slot coil, dipole coil, helical coil, spiral coil, fractal coil, and microstrip coil.

The present teachings provide a magnetic resonance system that has RF coils integrated with gradient coils such that a same amount of scanning may be performed or more scanning may be performed with fewer components, in a more compact space, or both.

The present teaches further provide the system with: the magnet in MRI system is one of an electromagnetic magnet, a permanent magnet, and a superconductive magnet; at least one of the one or more first electrically conductive loops is shared with at least one of the one or more second electrically conductive loops; the one or more first electrically conductive loops and the one or more second electrically conductive loops are directly physically connected, directly electrically connected, or both; the portion of the one or more electrically conductive loops and the one or more second electrically conductive loops that are shared are located inside of a non-shared portion of the gradient coils; the portion of the one or more electrically conductive loops and the one or more second electrically conductive loops that are shared are located outside of a non-shared portion of the gradient coils; at least one switch is coupled to a control circuit; the control circuit is configured to selectively activate the at least one switch of the one of the pluralities of electrically conductive loops thereby generating radiofrequency fields to excite nuclear spins or receiving MRI signal around a Larmor frequency in the MRI system; currents for the radiofrequency coils and the gradient coils coexist independently in the one or more first electrically conductive loops and the one or more second electrically conductive loops that are shared; a coexistence of the radiofrequency loops and the gradient loops can reduce interference or interaction partly between radiofrequency loops and gradient loops; a direction of a magnetic field generated by at least a part of the one of the one or more first electrically conductive loops are parallel to a static magnetic field generated by the magnet; a direction of a magnetic field generated by at least a part of the one or more second electrically conductive loops are perpendicular to a static magnetic field generated by the magnet; at least one of the radiofrequency coils provides a radiofrequency transmission, a radiofrequency reception, or both in the MRI system; a single-layer electrically conductive loops; multi-layer electrically conductive loops; or a combination thereof.

The present teachings provide a system and/or apparatus with: a magnet in the MRI apparatus that is one of an electromagnetic magnet, a permanent magnet, and a superconductive magnet; the one or more first part of the plurality of electrically conductive loops and the one or more second part of the electrically conductive loops are directly physically connected, directly electrically connected, or both; at least one switch coupled to a control circuit, wherein the control circuit is configured to selectively activate the at least one switch of the one of the pluralities of electrically conductive loops thereby generating a radiofrequency fields to excite nuclear spins or receiving MRI signal around a Larmor frequency in the MRI apparatus; a direction of a magnetic field generated by the one or more first part of the plurality of electrically conductive loops extends parallel to that of a static magnetic field generated by the magnet; a direction of a magnetic field generated by the one or more second part of the plurality of electrically conductive loops extend perpendicular to a static magnetic field generated by the magnet; or a combination thereof.

Other systems, methods, features and/or advantages will be or may become apparent to one with skill in the art upon examination of the following drawings and detailed description. All such additional systems, methods, features and/or advantages included within this description may be protected by the accompanying claims.

The present teachings provide a magnetic resonance system that has a part of one or more RF coils integrated with part of one or more gradient coils such that a same amount of scanning may be performed or more scanning may be performed with fewer components, in a more compact space, or both.

### BRIEF DESCRIPTION OF DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1A is a diagram illustrating an example of a vertical B₀ portable a magnetic resonance system.

FIG. 1B is a diagram illustrating another example of a vertical B_{O} portable magnetic resonance system with a partially shared gradient and radiofrequency coil.

FIG. 2A illustrates an example of a plurality of gradient coils in an X-direction used for the vertical B₀ portable a magnetic resonance system in shown in FIG. 1A.

FIG. 2B illustrates an example of a plurality of gradient coils in a Y-direction used for the vertical B₀ portable a magnetic resonance system in shown in FIG. 1A.

FIG. 2C is an example of a conductive loop used as a gradient coil in a Z-direction used for the vertical B₀ portable a magnetic resonance system in shown in FIG. 1A.

FIG. 3 is a graphical representation of a Z gradient coil (FIG. 2C) having linearity in region of interest.

FIG. 4 is an exemplary driven circuit for a conductive loop shown in FIG. 2C as a transmit coil with a quadrature drive.

FIG. 5 is a simulated B₁⁺ magnitude of the exemplary quadrature transmit coil shown in FIG. 4.

FIG. 6 is an exemplary driven circuit for integrated driven of a shared radiofrequency coil and the Z gradient coil shown in FIG. 2C.

### DETAILED DESCRIPTION

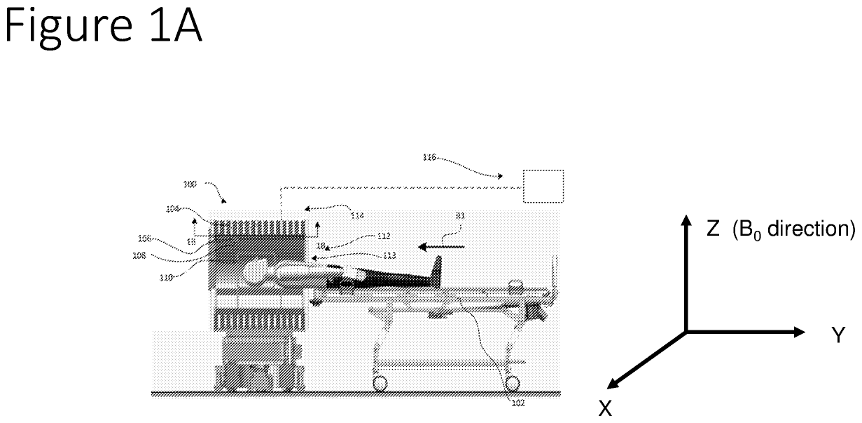

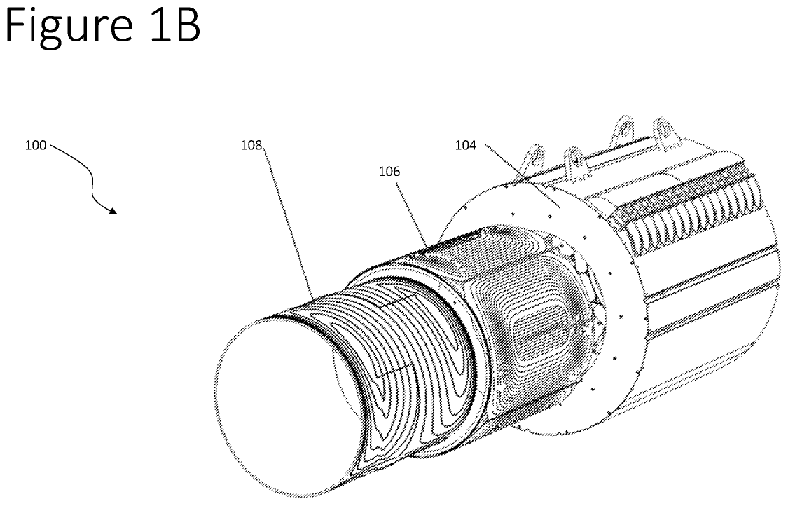

FIG. 1A is a diagram illustrating a radio-frequency apparatus (e.g., a portable MRI/MRSI system) 100 with a horizontal B₁. The system 100 may be a fixed system, but as depicted is a portable system 100. The portable system 100 may be movable and usable with any patient table 102 or bed. The patient table may be raised or lowered to a height of the portable system 100 or the portable system 100 may be raised or lowered to a height of the patient table 102. The portable system 100 includes a permanent magnet 104. The permanent magnet 104 surrounds the patient while the patient is located in a magnet bore 113 of the permanent magnet 104. The permanent magnet 104 may work in conjunction with radiofrequency coils 108 (e.g., quadrature transmission coils, or RF transceiver coils).

The gradient coils 106 may create gradient magnetic fields for spatial encoding in any direction of an x, y, z, coordinate system. The radiofrequency coils 108 may be radiofrequency transmission coils (RF TX coil) which transmit magnetic fields to excite nuclear spins for an MRI or MRSI. The coils 108 can be shared as the part of gradient coils 106 that provides one or more of gradient encoding along one or more of the x, y, z coordinate directions. Thus, the combined coils 108 are used as the part of gradient coils 106 for spatial encoding.

The second set of coils 110 receive and measure the induced electromagnetic signal by the nuclear spins.

A magnet resonance imaging system (MRI/MRSI) 100 including: a magnet 104; gradient coils 106 including one or more first electrically conductive loops that provide spatial encoding as to a subject of the system 100; and radiofrequency coils 108 including one or more second electrically conductive loops that transmit a radiofrequency field to excite nuclear spins and/or receive a MRI signal; wherein all or a portion of the one or more first electrically conductive loops and the one or more second electrically conductive loops are shared. At least one of the radiofrequency coils 108 may provide a radiofrequency transmission, a radiofrequency reception, or both in the MRI system 100. The system 100 may have a single-layer of electrically conductive loops. The system 100 may have a multi-layer of the electrically conductive loops.

A magnetic resonance imaging (MRI) apparatus 100 may include a plurality of electrically conductive loops; at least one or more first part of the plurality of the electrically conductive loops may provide spatial encoding in the MRI apparatus 100; and at least one or more second part of the plurality of the electrically conductive loops may provide radiofrequency transmissions that excite nuclear spins and/or reception of MRI radiofrequency signals in the MRI apparatus 100; all or a portion of the one or more first part of the plurality of electrically conductive loops and the one or more second part of the electrically conductive loops are shared.

The magnet 104 may be an electromagnetic magnet, a permanent magnet, a superconductive magnet, or a combination thereof. Currents of the radiofrequency coils 108 and the gradient coils 106 may coexist independently in the one or more first electrically conductive loops and the one or more second electrically conductive loops that are shared. The coexistence of the radiofrequency loops and the gradient loops can reduce interference or interaction partly between radiofrequency loops and gradient loops. A direction of a magnetic field generated by at least a part of the one of the one or more first electrically conductive loops may be parallel or may be perpendicular to a static magnetic field generated by the magnet 104.

FIG. 1B illustrates an exemplary diagram of a vertical B₀ portable magnetic resonance system 100 with a magnet 104 and a partially shared gradient coil 106 and radiofrequency coil 108. In this design, a conductive loop serves as both the radiofrequency coil 108 and the Z-axis gradient coil 106, leading to numerous advantages. Firstly, the combined use of the conductive loop saves valuable space compared to having separate coils for each function. This compact design enhances the portability of the system, making it easier to use in a variety of settings.

Additionally, the shared conductive loop results in cost savings as it eliminates the need to purchase and integrate two separate coils. Furthermore, the combined coil design leads to greater efficiency, as it reduces the number of components required for the system and streamlines the overall imaging process.

Finally, the shared conductive loop has the potential to improve the quality of imaging, as the radiofrequency coil 108 and gradient coil 106 can be optimized for each other. This provides in enhanced signal-to-noise ratio and improved overall image quality.

In conclusion, the partially shared gradient coil 106 and radiofrequency coil 108 in the vertical B₀ portable magnetic resonance system provides a cost-effective, space-saving, and efficient solution with improved imaging quality.

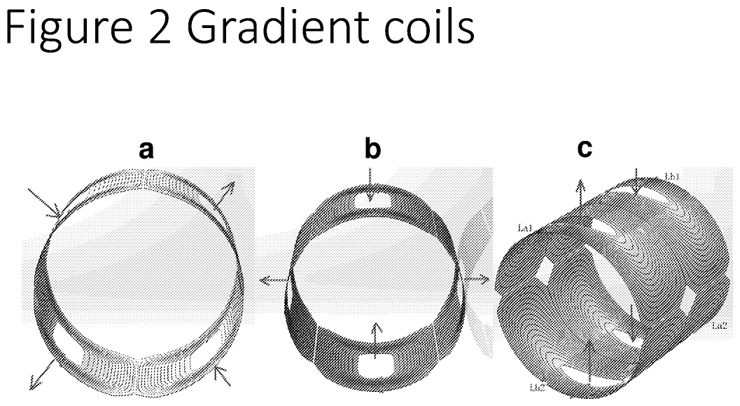

FIGS. 2a-2c illustrate examples of a plurality of gradient coils (i.e. X (2a), Y (2b), and Z (2c) gradient coil) used for the vertical B₀ portable MRI/MRSI system in shown in FIG. 1. Each gradient coil set is driven by an independent power amplifier (not shown). The gradient coils in FIG. 2a-c respectively create a gradient field whose z-component varies linearly along the x-, y-, and z-directions, and encode spatial information into the magnetic resonance system of FIG. 1.

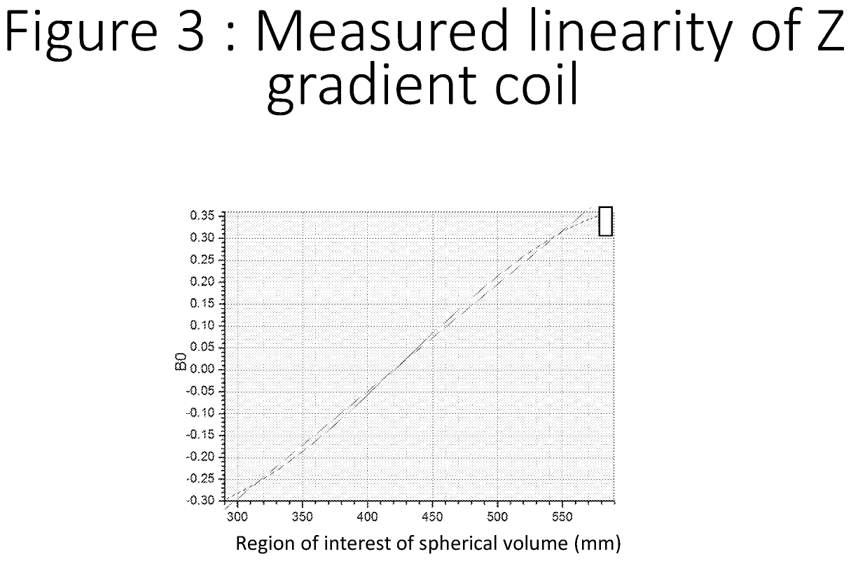

FIG. 3 illustrates a graphical representation of a Z gradient coil having gradient linearity. In FIG. 3, the linearity of the z-gradient has a linearity error of less than 5% within 240 mm (from 320 to 560 mm) of a defined spherical volume (DSV). The non-linearity of Z gradient coil as demonstrated by the curve meets the criteria that American College of Radiology (ACR) guides MRI acceptance testing for MRI gradient coils.

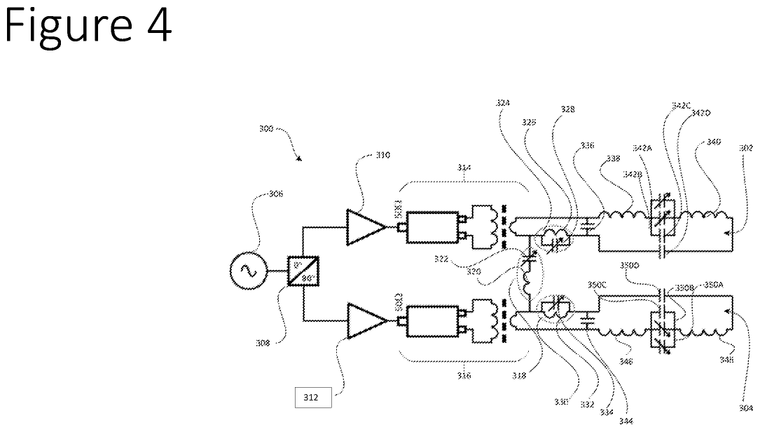

FIG. 4 illustrates a circuit 300 for a radiofrequency transmit coil that is quadrature driven. The circuit includes an A circuit side 302 and a B circuit side 304. The circuit 300 is connected to a transmitted RF signal source 306. The transmitted RF signal source 306 is controlled by an MRI spectrometer.

The Quadrature phase shifter 308 is mainly a quadrature coupler which splits the input signal into two signals 90 degrees out of phase from one another. The phase shifter 308 between the A circuit side 302 and the B circuit side 304 is 90 degrees to maximize positive circularly polarized RF field components in quadrature driven. For a transmit coil with a linear driven, the phase shifter 308 is 0 degree.

From the phase shifter 308 the RF signal source extends into a first RF power amplifier 310 on the A circuit side 302 and a second RF power amplifier 312 on the B circuit side 304. The first amplifier 310 may amplify the RF signal of low level to have an amplitude. The second amplifier 312 may amplify the signal of low level to have an amplitude. After the first voltage amplifier 310 amplifies the RF signal, the RF signal extends into a transformer, which as shown is a first balun transformer 314. After the second voltage amplifier 312 amplifies the signal, the signal extends into a transformer, which as shown is a second balun transformer 316.

The first balun transformer 314 and the second balun transformer 316 function to provide a flow of AC signals, change impedance of a voltage, balance loads of the signals, change an impedance, or a combination thereof. The first balun transformer 314, the second balun transformer 316, or both may provide a balanced output. The first balun transformers 314, the second balun transformers 316, or both may receive an unbalanced input and provide a balanced output, balance between a first side and a second side of a respective one of the first balun transformer 314 and/or the second balun transformer 316. A first side of the first balun transformers 314 and the second balun transformers 316 receives the voltage and then outputs the voltage to a second side of the first balun transformers 314 and the second balun transformers 316 respectively. The second side of the first balun transformers 314 and the second balun transformers 316 are connected by a connector LC circuit 318.

The connector LC circuit 318 includes an inductor 320 and a variable capacitor 322. The connector LC circuit 318 is used for decoupling between the A circuit 302 and the B circuit 304. The connector LC circuit 318 may act as a bandpass filter, be tunable, balance the A circuit 302 relative to the B circuit 304.

The voltage in the A circuit 302 extends from the first balun transformer 314 and through an A LC circuit 324. The A LC circuit 324 includes an inductor 326 and a variable capacitor 328. The variable capacitor 328 can cause an adjustable complex impedance at the Larmor frequency.

After the A LC circuit 324 the voltage extends through a capacitor 336 to a first A conductive loop 338 and a second A conductive loop 340. The conductive loops 338 and 340 create one channel of a quadrature transmit radiofrequency coil. A plurality of capacitors that include capacitors 342A-D. Some of the capacitors 342A-D may be static capacitors and some may be variable capacitors so that the A LC circuit 302 may be tuned, decoupled, varied, or a combination thereof at the Larmor frequency.

The voltage in the B circuit 304 after extending through the second balun transformer 316 may extend through a B LC circuit 330. The B LC circuit 330 includes an inductor 332 and a variable capacitor 334 that constitute a parallel complex impedance. The variable capacitor 334 can cause an adjustable complex impedance at the Larmor frequency. After the B LC circuit 330, the voltage extends through a capacitor 344 to a first B conductive loop 346 and a second B conductive loop 348. The conductive loops 346 and 348 create one channel of a quadrature transmit radiofrequency coil. Some of the plurality of capacitors 350A-D may be static capacitors and some may be variable capacitors so that the voltage may be tuned, decoupled, varied, or a combination thereof at the Larmor frequency.

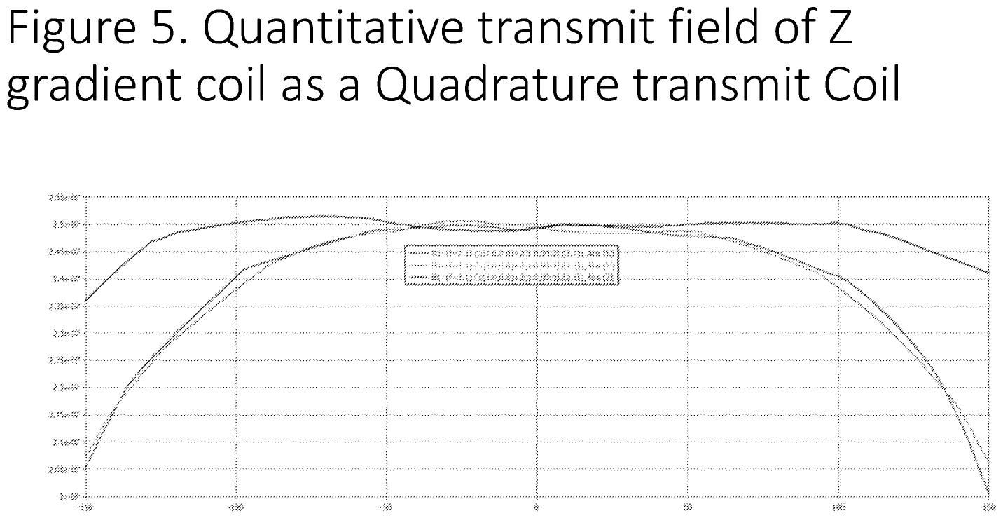

Inductor 320 and the adjustable capacitance 322 constitute a series complex impedance that may be used to adjust the variable capacitor 322 to change the impedance and improve the performance of the network at the Larmor frequency. FIG. 5 illustrates a B₁⁺ magnitude of the quadrature coil shown in FIG. 2c. The B₁⁺ magnitude of the quadrature transmit coils 108 is shown along different orientations. The inhomogeneity of B₁⁺ magnitude within a spherical diameter of 50 mm is less than 1% along a z direction, 3% along both x and y directions. As shown, between 50 mm and −50 mm all three of the x, y, and z directions substantially overlap at about 0.25 micro-Tesla. This overlap demonstrates the homogeneity of the different orientations relative to 0 (e.g., a center) of the spherical diameter. As shown, the directions begin to diverge away from one another as the directions (e.g., x, y, and z) approach an outer diameter of the sphere (e.g., 150 mm and −150 mm). The directions begin to diverge around 50 mm and −50 mm and the slope of the divergence increases as the directions approach 150 and −150 respectively. A magnitude of fields generated by the first coil resonator and the second coil resonator is equal to or very close to a most regions (e.g., within about 1% or less). A phase difference between the first coil resonator and the second coil resonator may be about 90 degrees.

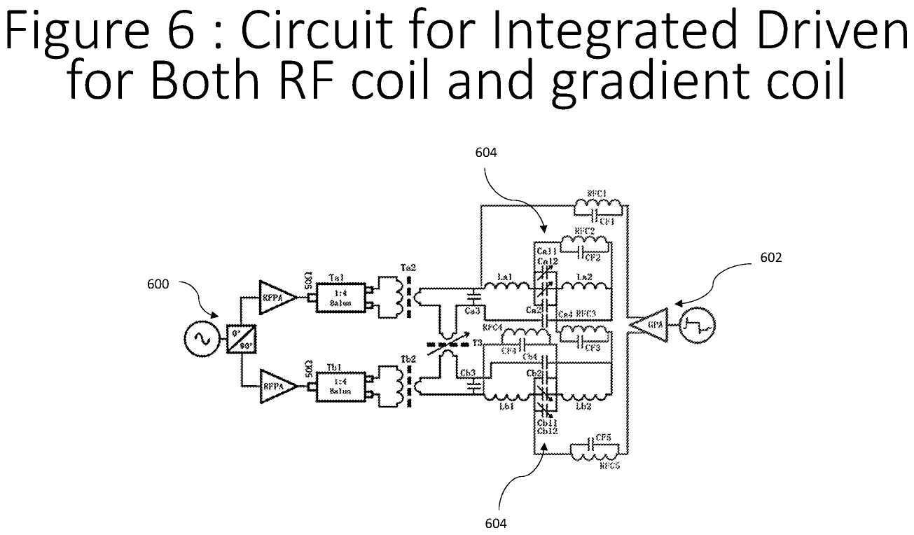

FIG. 6 is an exemplary driven circuits 600 and 602 for respectively driving shared conductive loops La1, La2, Lb1 and Lb2 used for a radiofrequency coil and a Z gradient coil shown in FIG. 2c. The conductive loops La1, La2, Lb1 and Lb2 (i.e., FIG. 2c) of the first conductive loops (i.e., FIGS. 2a-2c) may be shared with the conductive loops La1, La2, Lb1 and Lb2 one or more second electrically conductive loops (i.e., FIG. 2c). The one or more first conductive loops may be directly physically connected, directly electrically connected, or both with one or more second electrically conductive loops. The portion of the one or more first electrically loops and the one or more second electrically conductive loops that are shared may be located inside or outside of a non-shared portion of the gradient coils. The driven circuit 600 includes a network 604 that blocks all or a portion of a radio frequency coil. The driven circuit 600 (e.g., a control circuit) may be configured to selectively activate the at least one switch of the one of the pluralities of electrically conductive loops thereby generating radiofrequency fields to excite nuclear spins or receiving MRI signal around a Larmor frequency in the MRI system 100. The driven circuit 600 may include a switch. The control circuit 600 may be configured to selectively activate the at least one switch of the one of the pluralities of electrically conductive loops thereby generating a radiofrequency fields to excite nuclear spins or receiving MRI signal around a Larmor frequency in the MRI apparatus.

The network 604 includes RFC1/CF1, RFC2/CF2, RFC3/CF3, RFC4/CF4, and RFC5/CF5 circuits that each block some of the radio frequency coil. The network 604 has a resonance frequency that is at the Larmor frequency of nuclear spins at the given static field strength. A frequency of a gradient field generated by the driven circuit 602 may be lower than the Larmor radiofrequency that the inductors RFC1 to RFC5 provide such that a current path for driving the Z gradient coil that generate the gradient field at the frequency range that is a DC to low frequency band. The driven circuit 602 includes a plurality of capacitors. The capacitors (cal1, cal2, cbl1 and cbl2) are used to block current paths of low frequency direct current (DC) from the Z gradient coil. In the frequency band from DC to low frequency, RFC2/CF2 and RFC4/CF4 appear a dual/symmetrical structure.

The shared conductive loops La1, La2, Lb1 and Lb2 that are used for a radiofrequency coil and a Z gradient coil shown in in FIG. 2c. may be simultaneously and independently operated or driven by Circuit 600 in a radiofrequency mode for at least one of transmit or receive and (ii) by circuit 610 in a gradient mode for spatial encoding of the given direction.

The present provides a proof-of-concept prototype that may integrate part of one or more gradient coils into part of one or more RF coils in a magnetic resonance system. The present teachings provide a method to integrate the part of radiofrequency coils and the part of gradient coils in a magnetic resonance system. The present invention can teach partly (1) reduce the cost of both conductive coil and the shielding between gradient coils and radiofrequency coils by eliminating some of the excess structure for both radiofrequency and/or gradient coils and their respective shielding; (2) increase effective space of a magnet and partly simplify the hardware of MRI system by eliminating some of the excess internal structures; (3) mitigate the claustrophobic conditions and improve the patients' comfortability by increased patient's space; (4) improve the performance of the z gradient coils and the radiofrequency coils by increased effective space; and (5) finally improve the image quality.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A magnet resonance system comprising:
a magnet;
gradient coils comprising one or more first electrically conductive loops that provide spatial encoding as to a subject of the system; and
radiofrequency coils comprising one or more second electrically conductive loops that transmit a radiofrequency field to excite nuclear spins and/or receive a MRI signal;
wherein all or a portion of the one or more first electrically conductive loops and the one or more second electrically conductive loops are shared.

2. The system of claim 1, wherein the magnet in MRI system is one of an electromagnetic magnet, a permanent magnet, and a superconductive magnet.

3. The system of claim 1, wherein at least one of the one or more first electrically conductive loops is shared with at least one of the one or more second electrically conductive loops.

4. The system of claim 1, wherein the one or more first electrically conductive loops and the one or more second electrically conductive loops are directly physically connected, directly electrically connected, or both.

5. The system of claim 1, wherein the portion of the one or more first electrically conductive loops and the one or more second electrically conductive loops that are shared are located inside of a non-shared portion of the gradient coils.

6. The system of claim 1, wherein the portion of the one or more electrically conductive loops and the one or more second electrically conductive loops that are shared are located outside of a non-shared portion of the gradient coils.

7. The system of claim 1, wherein at least one switch is coupled to a control circuit,
wherein the control circuit is configured to selectively activate the at least one switch of the one of the pluralities of electrically conductive loops thereby generating radiofrequency fields to excite nuclear spins or receiving MRI signal around a Larmor frequency in the MRI system.

8. The system of claim 1, wherein currents for the radiofrequency coils and the gradient coils coexist independently in the one or more first electrically conductive loops and the one or more second electrically conductive loops that are shared.

9. The system of claim 8, wherein a coexistence of the radiofrequency loops and the gradient loops can reduce interference or interaction partly between radiofrequency loops and gradient loops.

10. The system of claim 1, wherein a direction of a magnetic field generated by at least a part of the one of the one or more first electrically conductive loops are parallel to a static magnetic field generated by the magnet.

11. The system of claim 1, wherein a direction of a magnetic field generated by at least a part of the one or more second electrically conductive loops are perpendicular to a static magnetic field generated by the magnet.

12. The system of claim 11, wherein at least one of the radiofrequency coils provides a radiofrequency transmission, a radiofrequency reception, or both in the MRI system.

13. The system of claim 1, further comprising single-layer electrically conductive loops.

14. The system of claim 1, further comprising multi-layer electrically conductive loops.

15. A magnetic resonance imaging (MRI) apparatus comprising:
a plurality of electrically conductive loops;
at least one or more first part of the plurality of the electrically conductive loops provides spatial encoding in the MRI apparatus; and
at least one or more second part of the plurality of the electrically conductive loops provides radiofrequency transmission that excite nuclear spins and/or reception of MRI radiofrequency signals in the MRI apparatus;
wherein all or a portion of the one or more first part of the plurality of electrically conductive loops and the one or more second part of the electrically conductive loops are shared.

16. The apparatus of claim 15, further comprising:
a magnet in the MRI apparatus that is one of an electromagnetic magnet, a permanent magnet, and a superconductive magnet.

17. The apparatus of claim 15, wherein the one or more first part of the plurality of electrically conductive loops and the one or more second part of the electrically conductive loops are directly physically connected, directly electrically connected, or both.

18. The apparatus of claim 15, further comprising:
at least one switch coupled to a control circuit,
wherein the control circuit is configured to selectively activate the at least one switch of the one of the pluralities of electrically conductive loops thereby generating a radiofrequency fields to excite nuclear spins or receiving MRI signal around a Larmor frequency in the MRI apparatus.

19. The apparatus of claim 16, wherein a direction of a magnetic field generated by the one or more first part of the plurality of electrically conductive loops extends parallel to that of a static magnetic field generated by the magnet.

20. The apparatus of claim 16, wherein a direction of a magnetic field generated by the one or more second part of the plurality of electrically conductive loops extend perpendicular to a static magnetic field generated by the magnet.
